(19) United States
(12) Patent Application Publication
(10) Pub. No.: US 2026/0076152 A1
(43) Pub. Date: Mar. 12, 2026

(54) SEMICONDUCTOR STRUCTURES HAVING BACKSIDE METAL DIE DAMAGE RINGS AND METHODS FOR MANUFACTURING AND TESTING THEREOF

(71) Applicant: Taiwan Semiconductor Manufacturing Company, Ltd., Hsinchu (TW)

(72) Inventors: Cing-Yao Jhan, Hsinchu (TW); Tsung-Yu Chiang, New Taipei City (TW); Chi-Ruei Yeh, New Taipei City (TW)

(73) Assignee: Taiwan Semiconductor Manufacturing Company, Ltd., Hsinchu (TW)

(21) Appl. No.: 18/882,231

(22) Filed: Sep. 11, 2024

(51) Int. Cl. H01L 21/66; H01L 21/768; H01L 23/528; H01L 23/58

(52) U.S. Cl. CPC H10P 74/273; H10P 74/207; H10P 74/277; H10W 20/023; H10W 20/43; H10W 42/00

(57) ABSTRACT

Semiconductor structures and methods for manufacturing and testing semiconductor structures are provided. The semiconductor structures include an integrated circuit formed in a semiconductor substrate, a seal ring on at least a first side of the semiconductor substrate and surrounding a perimeter of the integrated circuit, an input element, an output element, and a backside metal die damage ring (BMDDR) disposed on the first side of the semiconductor substrate, extending through the semiconductor substrate, and disposed on a second side of the semiconductor substrate, the BMDDR disposed between the integrated circuit and the seal ring, the BMDDR at least partially surrounding the perimeter of the integrated circuit, the BMDDR coupled to and forming an electrical circuit between the input element and the output element.

### BACKGROUND

The semiconductor integrated circuit (IC) industry has continued its rapid growth in recent years. Technological advancements in IC materials and design have led to continuous improvements in the generations of ICs. With each new generation, the circuits become smaller and more complex than their predecessors, resulting in higher functional density (i.e., the number of interconnected devices per chip area) and smaller geometric sizes (i.e., the smallest component or line that can be created using a fabrication process). This scaling down process has been beneficial in increasing production efficiency and reducing associated costs. However, as feature sizes continue to shrink, the manufacturing process becomes more challenging, and it becomes increasingly difficult to ensure the reliability of semiconductor devices. As a result, the industry faces the ongoing challenge of developing processes that can create smaller, more reliable ICs.

### BRIEF DESCRIPTION OF DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of a portion of an exemplary semiconductor structure at one stage in an integrated circuit manufacturing process in accordance with an embodiment;

FIG. 2 is a top view of a portion of the exemplary semiconductor structure of FIG. 1 in accordance with an embodiment;

FIG. 3 is a cross-sectional view illustrating a portion of an exemplary seal ring of the semiconductor structure of FIG. 1 in accordance with an embodiment;

FIG. 4 is a cross-sectional view illustrating a portion of an exemplary backside metal damage detection ring (BMDDR) of the semiconductor structure of FIG. 1 in accordance with an embodiment;

FIG. 5 is a cross-sectional view illustrating a portion of an exemplary BMDDR of the semiconductor device of FIG. 1 in accordance with an embodiment;

FIG. 6 schematically represents a serpentine pattern of an electrical circuit formed by the BMDDR of FIG. 5 in accordance with an embodiment;

FIG. 7 is a cross-sectional view illustrating exemplary dimensions of the BMDDR of FIG. 5 in accordance with an embodiment;

FIG. 8 is a cross-sectional view illustrating an exemplary semiconductor device of the BMDDR of FIGS. 5 and 7 in accordance with an embodiment;

FIG. 9 is a cross-sectional view of a portion of another exemplary semiconductor structure at one stage in an integrated circuit manufacturing process in accordance with an embodiment;

FIG. 10 is a cross-sectional view of a portion of yet another exemplary semiconductor structure at one stage in an integrated circuit manufacturing process in accordance with an embodiment;

FIG. 11 is a cross-sectional view of a portion of yet another exemplary semiconductor structure at one stage in an integrated circuit manufacturing process in accordance with an embodiment;

FIG. 12 is a flowchart illustrating an exemplary method for forming and testing a semiconductor structure in accordance with an embodiment;

FIG. 13 is a flowchart illustrating an exemplary method for testing a semiconductor structure in accordance with an embodiment;

FIG. 14 is a flowchart illustrating an exemplary method for fabrication of a semiconductor structure in accordance with an embodiment; and

FIGS. 15-20 illustrate certain nonlimiting steps of the method of FIG. 14 in accordance with an embodiment.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

As used herein, the terms such as “first,” “second” and “third” describe various elements, components, regions, layers and/or sections, but these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

For the sake of brevity, conventional techniques related to conventional semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many conventional processes will only be mentioned briefly herein or will be omitted entirely without providing the well-known process details. As will be readily apparent to those skilled in the art upon a complete reading of the disclosure, the structures disclosed herein may be employed with a variety of technologies and may be incorporated into a variety of semiconductor devices and products. Further, it is noted that semiconductor device structures include a varying number of components and that single components shown in the illustrations may be representative of multiple components.

Furthermore, spatially relative terms, such as “over”, “overlying”, “above”, “upper”, “top”, “under”, “underlying”, “below”, “lower”, “bottom”, and the like, may be used herein for ease of description to describe one element's or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When a spatially relative term, such as those listed above, is used to describe a first element with respect to a second element, the first element may be directly on the other element, or intervening elements or layers may be present. When an element or layer is referred to as being “on” another element or layer, it is directly on and in contact with the other element or layer.

It is noted that references in the specification to “one embodiment,” “an embodiment,” “an example embodiment,” “exemplary,” “example,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to affect such feature, structure, or characteristic in connection with other embodiments whether or not explicitly described.

Some embodiments of the disclosure will now be described with reference to the drawings, wherein like reference numerals are generally used to refer to like elements throughout. In the following description, for purposes of explanation, numerous specific details are set forth in order to provide a thorough understanding of the claimed subject matter. It is evident, however, that the claimed subject matter may be practiced without these specific details. In other instances, structures and devices are illustrated in block diagram form in order to facilitate describing the claimed subject matter.

Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

As used herein, a “layer” is a region, such as an area comprising arbitrary boundaries, and does not necessarily comprise a uniform thickness. For example, a layer can be a region comprising at least some variation in thickness.

Fabrication of semiconductor devices typically includes forming of a plurality of integrated circuits on a single wafer, and then performing a die cutting (i.e., wafer dicing) process to separate the wafer into individual dies that each include one or more of the integrated circuits. While this process promotes mass production of semiconductor devices, there exists a possibility of damage occurring to one or more of the integrated circuits during the die cutting process. In such events, the damaged semiconductor device(s) may not function properly or may have reliability issues.

Presented herein are embodiments of semiconductor structures and methods for manufacturing and testing semiconductor structures having the capability to detect damage to integrated circuits thereof caused during a die cutting process. In various embodiments, the semiconductor structures include a die having a wafer or substrate with an integrated circuit formed therein. A damage detection element (referred to herein as a backside metal die damage ring (BMDDR)) defines a continuous electrical circuit that at least partially surrounds a perimeter of an integrated circuit formed in the substrate. A load may be applied to the BMDDR to detect a disconnect in the electrical circuit due to damage thereto, and thereby detect potential damage to the integrated circuit. In some examples, the disconnect may be detected by measuring a change in resistance (or conductivity) of the electrical circuit.

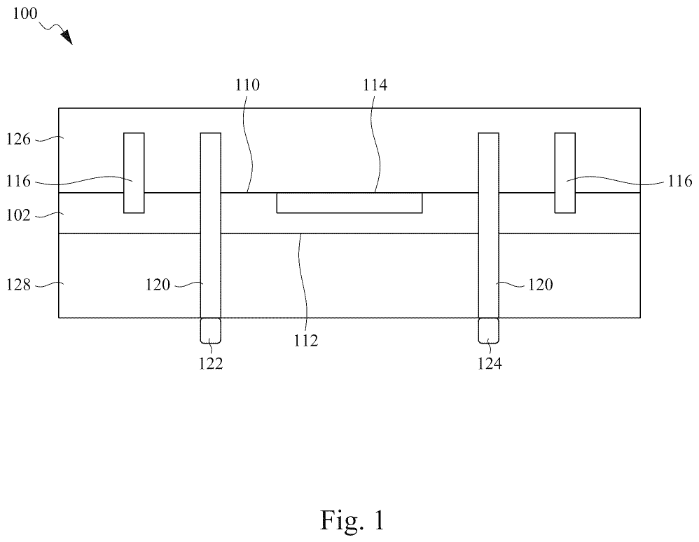

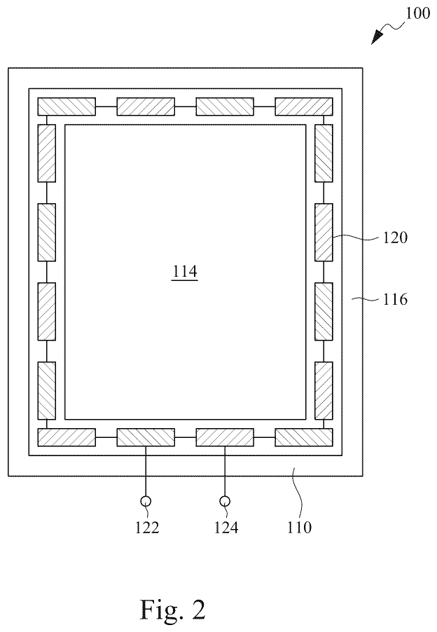

FIGS. 1 and 2 are cross-sectional and top views, respectively, of an exemplary semiconductor structure 100 at one stage in a manufacturing process in accordance with an embodiment. The semiconductor structure 100 includes a die having a semiconductor substrate 102 that includes a frontside 110 and a backside 112.

The semiconductor structure 100 includes an integrated circuit 114 formed in the semiconductor substrate 102. The integrated circuit 114 may include multiple interconnected electronic components such as transistors, resistors, and capacitors. The integrated circuit 114 may include or define various types of devices including, for example, a microprocessor, microcontrollers, memory, etc.

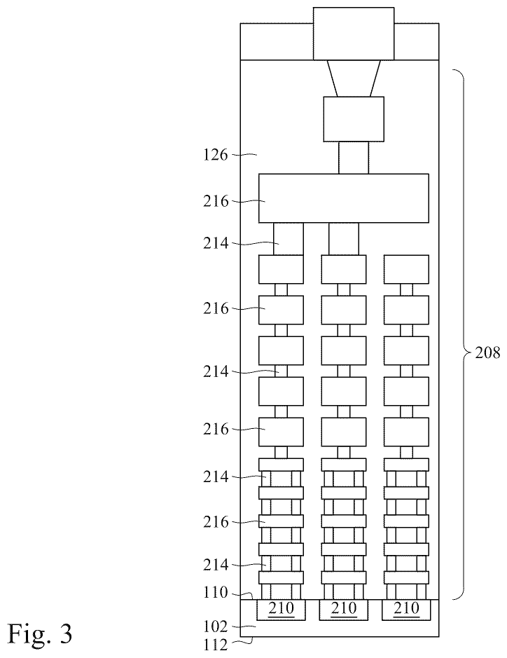

To reduce a likelihood of damaging the integrated circuit 114 during the die cutting process, the semiconductor structure 100 may include a seal ring 116 that is formed, in this example, on the frontside 110 of the semiconductor substrate 102 and that surrounds a perimeter of the integrated circuit 114. In this example, the seal ring 116 defines a square-shaped region; however, the seal ring 116 is not limited to this shape. The seal ring 116 may function as a physical barrier configured to promote protection of edges of the integrated circuit 114 during the manufacturing process. FIG. 3 is a cross-sectional view illustrating a portion of an exemplary seal ring 116. In this example, the seal ring 116 includes various first semiconductor devices 210 (e.g., transistor, capacitor, diode, etc.) formed in the semiconductor substrate 102, and a first interconnect structure 208 arranged over the semiconductor substrate 102 and the first semiconductor devices 210.

The first interconnect structure 208 may include a network of conductive, first interconnect metal layers 216 and first interconnect vias 214 surrounded by a first interconnect dielectric structure 126. The network of first interconnect metal layers 216 and first interconnect vias 214 of the first interconnect structure 208 may be electrically coupled to the first semiconductor devices 210.

The integrated circuit 114 and the seal ring 116 are spaced apart from each other on the semiconductor structure 100, and a BMDDR 120 is provided within the region between the integrated circuit 114 and the seal ring 116. The BMDDR 120 may partially or entirely surround the perimeter of the integrated circuit 114. The BMDDR 120 is coupled to an input element 122 (e.g., input pin) and an output element 124 (e.g., output pin). The BMDDR 120 defines a continuous electrical circuit between the input element 122 and the output element 124. A load may be applied between the input element 122 and the output element 124 to detect a disconnect in the electrical circuit of the BMDDR 120 due to damage thereto, and thereby detect potential damage to edges of the integrated circuit 114. In some examples, the disconnect may be detected by measuring a change in resistance (or conductivity) of the electrical circuit.

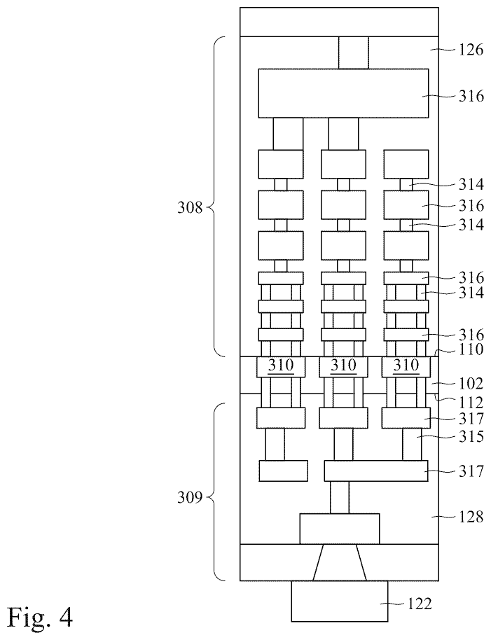

FIG. 4 is a cross-sectional view illustrating a portion of an exemplary BMDDR 120. In this example, the BMDDR 120 may include various second semiconductor devices 310 (e.g., transistor, capacitor, diode, etc.) formed in the semiconductor substrate 102, a second interconnect structure 308 arranged over the frontside 110 of the semiconductor substrate 102 and the second semiconductor devices 310, and a third interconnect structure 309 on a backside 112 of the semiconductor substrate 102. The second interconnect structure 308 and the third interconnect structure 309 may each be electrically connected to the second semiconductor devices 310 and thereby electrically connected to each other.

The second and third interconnect structures 308, 309 may include a network of conductive, second and third interconnect metal layers 316, 317 and second and third interconnect vias 314, 315 surrounded by the first and second interconnect dielectric structures 126, 128. The network of second and the third interconnect metal layers 316, 317 and second and third interconnect vias 314, 315 of the second and third interconnect structures 308, 309 may be electrically coupled to the second semiconductor devices 310. In some examples, the second interconnect metal layers 316 may be referred to as M1, M2, M3 . . . Mx, and the third interconnect metal layers 317 may be referred to as BM1, BM2, BM3 . . . BMx. In some examples, the second interconnect vias 314 may be referred to as V1, V2, V3 . . . Vx, and the third interconnect vias 315 may be referred to as BV1, BV2, BV3 . . . BVx. In some examples, the first interconnect dielectric structure 126 may include a plurality of first inter-metal dielectric (IMD) layers (not individually shown) that may be referred to as IMD1, IMB2, IMD3 . . . IMDx, and the second interconnect dielectric structure 128 may include a plurality of second inter-metal dielectric (IMD) layers (not individually shown) that may be referred to as BIMD1, BIMD2, BIMD3 . . . BIMDx.

In some examples, the semiconductor structures 100 may include various layers such as, but not limited to, the semiconductor substrate 102, inter-layer dielectric (ILD) layer(s), etc. In some embodiments, the semiconductor substrate 102 may be one of a variety of types of semiconductor substrates commonly employed in semiconductor integrated circuit fabrication. The semiconductor substrate 102 may be of any construction comprising semiconductor materials, including but not limited to, bulk silicon, a semiconductor wafer, a silicon-on-insulator (SOI) substrate, or a silicon germanium substrate. Other semiconductor materials, including group III, group IV, and/or group V semiconductors, can be used.

In some examples, the semiconductor substrate 102 may include a first inter-layer dielectric layer (ILD) over the first semiconductor devices 210, and contact plugs may be formed in the inter-layer dielectric layer for providing electrical connections between other circuitry/elements. The formation operations of the contact plugs can include forming openings in the inter-layer dielectric layer ILD, filling the openings with conductive materials, and performing a planarization such as chemical mechanical polishing (CMP). In some embodiments, the contact plugs can include tungsten (W), but other suitable conductive material such as silver (Ag), aluminum (Al), copper (Cu), or alloys thereof (AlCu) or the like.

The first and/or second IMD layers of the first and second interconnect dielectric structures 126, 128 may include one or more of low-k dielectric materials, fluorine-doped silicon dioxide, organosilicates, carbon-doped oxides, porous silicon dioxide, organic polymeric dielectrics (e.g., polyimide, polynorbornenes, benzocyclobutene, and PTFE), silicon based polymeric dielectrics (e.g., hydrogen silsesquioxane, methylsilsesquioxane), and other commonly used materials. The dielectric constants (k value) of the low-k dielectric materials can be less than about 3.9, less than about 3.5, or less than about 2.8.

In some embodiments, the first, second, and/or third interconnect metal layers 216, 316, 317 and the first, second, and/or third interconnect vias 214, 314, 315 may each include a single layer or two or more layers. In some embodiments, first, second, and/or third interconnect metal layers 216, 316, 317 and the first, second, and/or third interconnect vias 214, 314, 315 each include a fill material and a liner between the fill material and the dielectric material of the corresponding inter-metal dielectric layers. In some embodiments, the liner may include a noble metal or alloy thereof such as, but not limited to, rhenium (Re), rhodium (Rh), ruthenium (Ru), or alloys thereof. In some embodiments, the fill material may include copper (Cu), aluminum (Al), tungsten (W), silver (Ag), or alloys thereof.

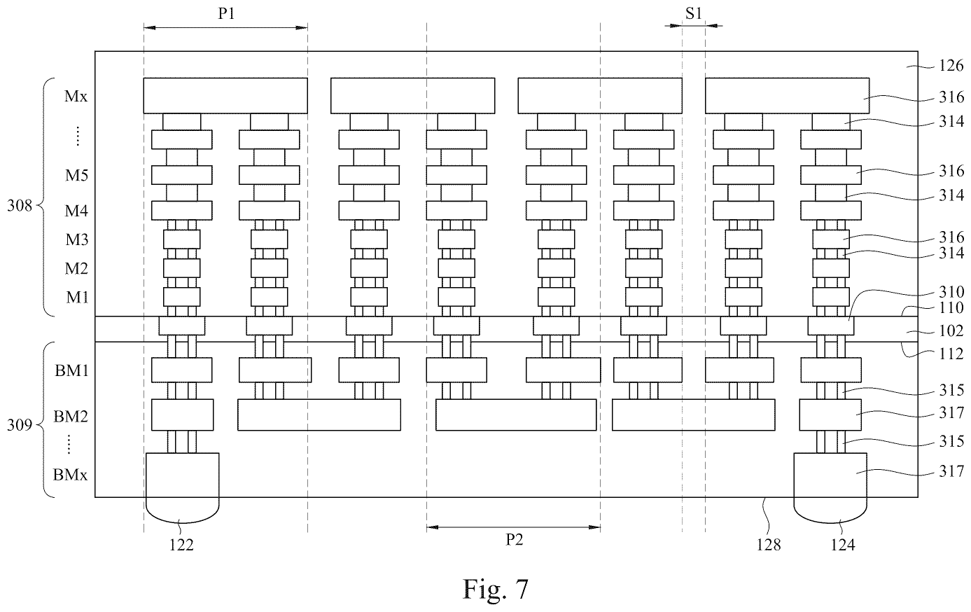

In some examples, the BMDDR 120 may be described as a series of electrically connected units each including a portion of the second interconnect structure 308 connected between two of the second semiconductor devices 310 or a portion of the third interconnect structure 309 connected between two of the second semiconductor devices 310. For example, FIG. 7 represents four first units 510 of the second interconnect structure 308 and three second units 512 of the third interconnect structure 309. In some examples, the BMDDR 120 includes a plurality of the first units 510 and a plurality of the second units 512 that are electrically coupled to each other in series such that the first units 510 and the second units 512 alternate linearly along the BMDDR 120.

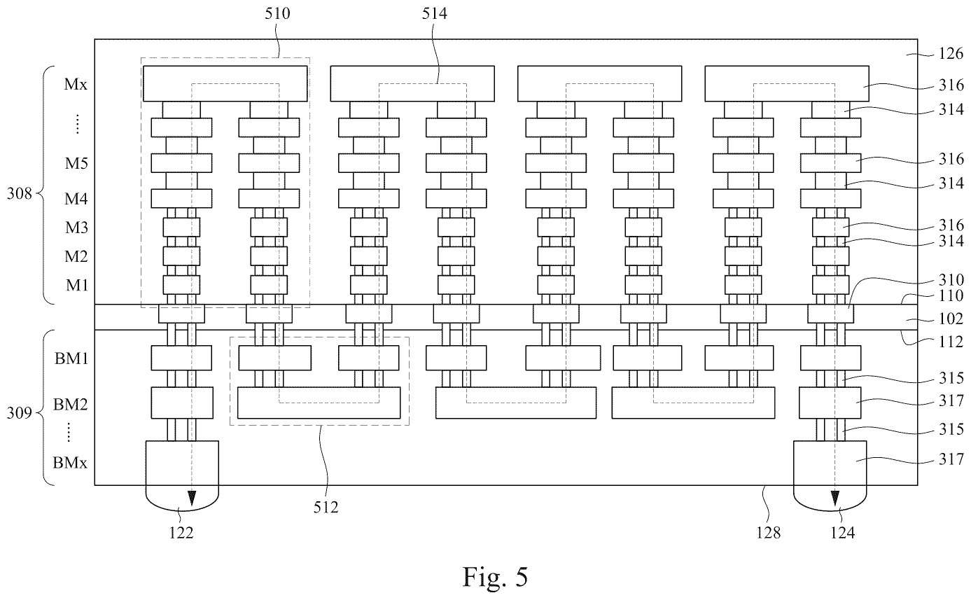

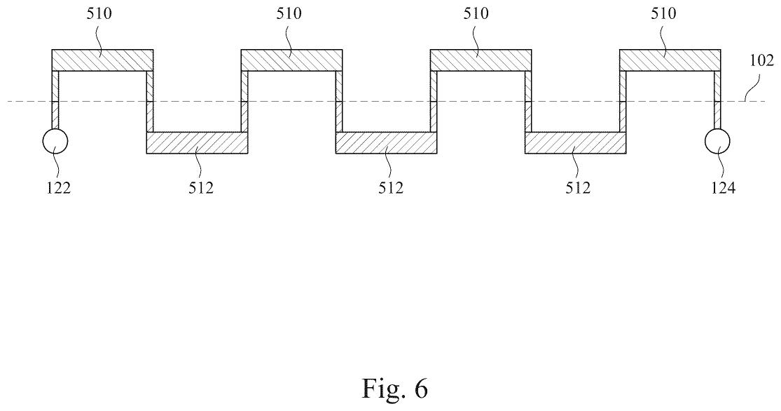

The BMDDR 120 may define electrical paths through the semiconductor structure 100 having various patterns. In the example of FIG. 5, an electric circuit 514 defined by the second interconnect structure 308, the third interconnect structure 309, and the second semiconductor devices 310 defines a serpentine pattern through the frontside 110 and the backside 112 of the semiconductor substrate 102. FIG. 6 schematically represents the serpentine pattern of FIG. 5. However, the BMDDR 120 is not limited to this pattern and may define various other patterns.

The various components of the semiconductor structure 100, including the BMDDR 120, may have various dimensions. For example, FIG. 7 presents the BMDDR 120 of FIG. 5 as having specific exemplary dimensions including a first pitch (P1; e.g., a dimension between ends of a first unit 510) of about 600 to about 800 nanometers (nm), a second pitch (P2; e.g., a dimension between ends of a second unit 512) of about 600 to about 800 nm, and a spacing (S1; e.g., a dimension between ends of two adjacent units) of about 1 to about 10 nm. Although FIG. 7 represents the BMDDR 120 as having consistent or uniformed sized first pitches (P1), second pitches (P2), and spacings (S1), these dimensions may vary depending on the application.

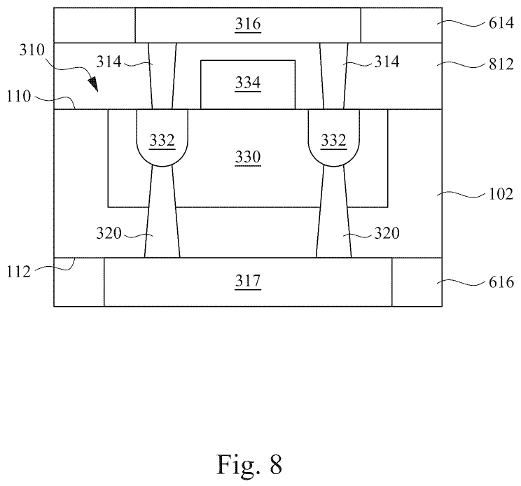

In some embodiments, the first and/or second semiconductor devices 210, 310 may be, for example, a metal oxide semiconductor field effect transistor (MOSFET). For example, FIG. 8 is a partial cross-sectional view of one of the second semiconductor devices 310. As represented, the second semiconductor devices 310 may comprise a doped well region 330 within the semiconductor substrate 102, wherein the doped well region 330 is more heavily doped and/or has a different doping type than the semiconductor substrate 102. Source/drain structures 332 may reside in the doped well region 330, and a gate electrode 334 over a gate dielectric layer (not shown) may be arranged on the frontside 110 of the semiconductor substrate 102 within a first IMD layer 812. In this disclosure, a source and a drain are interchangeably used, and the structures thereof are substantially the same.

Each of the source/drain structures 332 may be in electrical contact with the second interconnect structure 308 by respective ones of the second interconnect vias 314 within the first IMD layer 812 which in turn may be coupled to respective ones of the second interconnect metal layers 316 within a second IMD layer 614. Similarly, the source/drain structures 332 may be in electrical contact with the third interconnect structure 309 by respective through substrate vias (TSVs) 320 that extend through the backside 112 of the semiconductor substrate 102 which in turn may be coupled to respective ones of the third interconnect metal layers 317 within a third IMD layer 616.

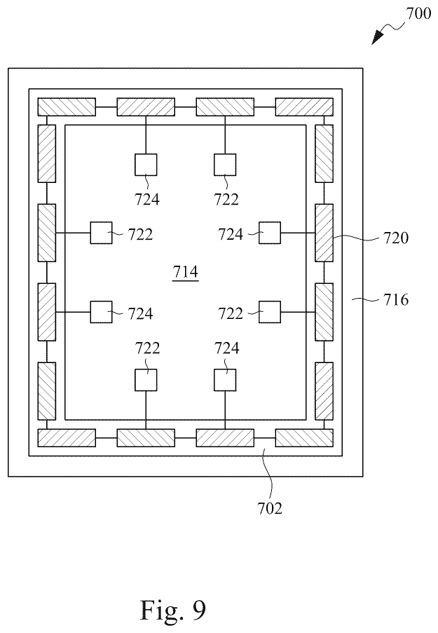

FIGS. 9-11 illustrate various nonlimiting alternative examples of semiconductor structures. It should be noted that these examples are merely for illustrative purposes and the semiconductor structures discussed herein may have other configurations, including various combinations of the components represented in FIGS. 9-11.

For convenience, consistent reference numbers are used throughout FIGS. 9-11 to identify the same or functionally related/equivalent elements as described in reference to FIGS. 1-8, but with a numerical prefix (1, 2, or 3, etc.) added to distinguish the particular example from other examples of the of the figures. In view of similarities between the examples, the following discussion of FIGS. 9-11 will focus primarily on aspects of the examples that differ from the other examples in some notable or significant manner. Other aspects of the examples not discussed in any detail can be, in terms of structure, function, materials, etc., essentially as was described for one or more of the other examples, including the examples of FIGS. 1-8.

FIG. 9 is a top view of a portion of an exemplary semiconductor structure 700 at one stage in a manufacturing process in accordance with an embodiment. The semiconductor structure 700 includes an integrated circuit 714 formed in a semiconductor substrate 702, a seal ring 716 surrounding a perimeter of the integrated circuit 714, and a BMDDR 720 between the integrated circuit 714 and the seal ring 716. In this example, the semiconductor structure 700 includes alternative input and output elements for the BMDDR 720. Specifically, the BMDDR 720 is electrically coupled to one or more input pads 722 and one or more output pads 724 of the integrated circuit 714. A load may be applied between any one of the input pads 722 and any one of the output pads 724 to detect a disconnect in the electrical circuit of the BMDDR 720. In some examples, the semiconductor structure 700 may include more than one of the input pads 722 and more than one of the output pads 724 to provide flexibility for operating the BMDDR 720. Although the BMDDR 720 is represented in this example as being continuous and entirely surrounding the integrated circuit 714, the BMDDR 720 may alternatively be discontinuous within one or more disconnections as along as the electrical circuits between pairs of the input pads 722 and the output pads 724 are conintuous.

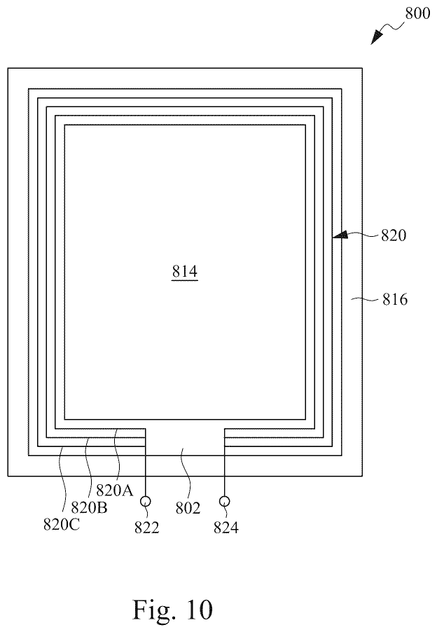

FIG. 10 is a top view of a portion of an exemplary semiconductor structure 800 at one stage in a manufacturing process in accordance with an embodiment. The semiconductor structure 800 includes an integrated circuit 814 formed in a semiconductor substrate 802, a seal ring 816 surrounding a perimeter of the integrated circuit 814, and a BMDDR 820 between the integrated circuit 814 and the seal ring 816. In this example, the BMDDR 820 includes three spaced apart interconnect systems 820A, 820B, 820C that are each at least partially surrounding the integrated circuit 814. Notably, the BMDDR 820 may include various quantities of the interconnect systems. In this example, all the interconnect systems 820A, 820B, 820C are electrically coupled to the input pin 822 and the output pin 824. Alternatively, one or more of the interconnect systems 820A, 820B, 820C may be electrically coupled to separate input and output elements.

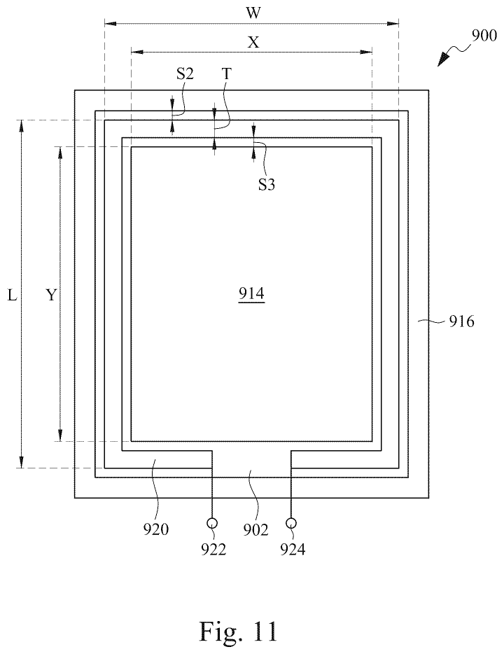

FIG. 11 is a top view of a portion of an exemplary semiconductor structure 900 at one stage in a manufacturing process in accordance with an embodiment. The semiconductor structure 900 includes an integrated circuit 914 formed in a semiconductor substrate 902, a seal ring 916 surrounding a perimeter of the integrated circuit 914, and a BMDDR 920 between the integrated circuit 914 and the seal ring 916. The BMDDR 920 is coupled to input and output pins 922, 924. In this example, the BMDDR 920 may have a thickness (T) of about 1 to 5 micrometers (μm), a spacing (S2) from the integrated circuit 914 of about 0.5 to 1.0 μm, and a spacing (S3) from the seal ring 916 of about 0.5 to 1.0μm. The perimeter of the BMDDR 920 may have a width (W) and a length (L) that are dependent on a size of the integrated circuit 914 as represented by a width (X) of the integrated circuit 814 and a length (Y) of the integrated circuit 814. In some examples, the width (W) of the BMDDR 920 may be defined by W=X+(2 T+2 S) and the length (L) of the BMDDR 920 may be defined by L=Y+(2 T+2 S).

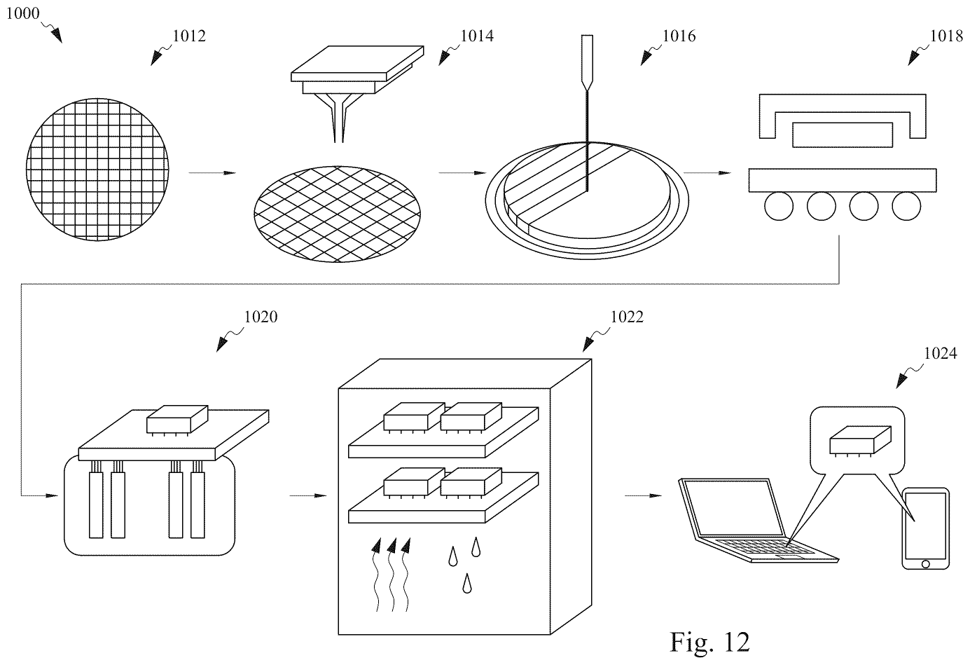

Referring to FIG. 12, an exemplary method 1000 is presented for manufacturing and testing a semiconductor structure. At 1012, the method 1000 includes fabrication of a plurality of integrated circuits on a wafer. Various physical and chemical processes may be used to form the various components of the integrated circuits. At least a first of the integrated circuits has a BMDDR partially or entirely surrounding a perimeter thereof. At 1014, the method 1000 includes performing a chip probing process to test some or all of the integrated circuits for functional defects. At 1016, the method 1000 includes performing a die cutting process to separate the wafer into a plurality of individual dice each of which may include one or more of the integrated circuits. At 1018, the method 1000 includes performing IC packaging. At 1020, the method 1000 includes performing final tests on the integrated circuit(s) of at least a first semiconductor structure that includes the first integrated circuit and the BMDDR, to ensure that required performance standards are met. During the final tests, a load may be applied to the BMDDR of the first semiconductor structure to detect potential damage to the first integrated circuit that may have occurred during the die cutting process. At 1022, the method 1000 includes performing reliability tests on the integrated circuit(s) of at least the first semiconductor structure. Various reliability tests may be performed such as, but not limited to, temperature cycling tests (TCTs), thermal shock tests, high temperature storage tests, temperature, humidity, and bias (THB) tests, highly accelerated temperature and humidity stress tests, high temperature operating life (HTOL) tests, and/or accelerated life tests (ALT). At 1024, the method 1000 includes installing the first semiconductor structure in a final product. The first semiconductor structure may be installed in various final products such as, but not limited to, computers, laptops, tablet computers, and smart phones.

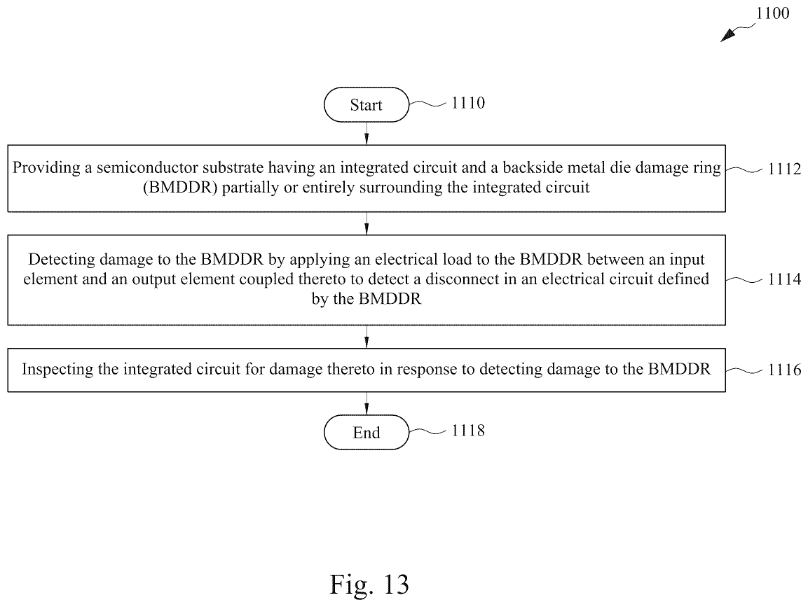

Referring to FIG. 13, an exemplary method 1100 is presented for testing a semiconductor structure. The method 1100 may start at 1110. At 1112, the method 1100 includes providing a semiconductor structure having an integrated circuit thereon and a BMDDR partially or entirely surrounding the integrated circuit. At 1114, the method 1100 may include applying a load to the BMDDR to detect potential damage to the integrated circuit. In some examples, the BMDDR defines an electrical circuit and a disconnect in the electrical circuit may be detected by measuring a change in resistance or conductivity of the electrical circuit. Optionally at 1116, the method 1110 may include inspecting the integrated circuit in response to detecting a disconnect in the BMDDR. The method 1100 may end at 1118.

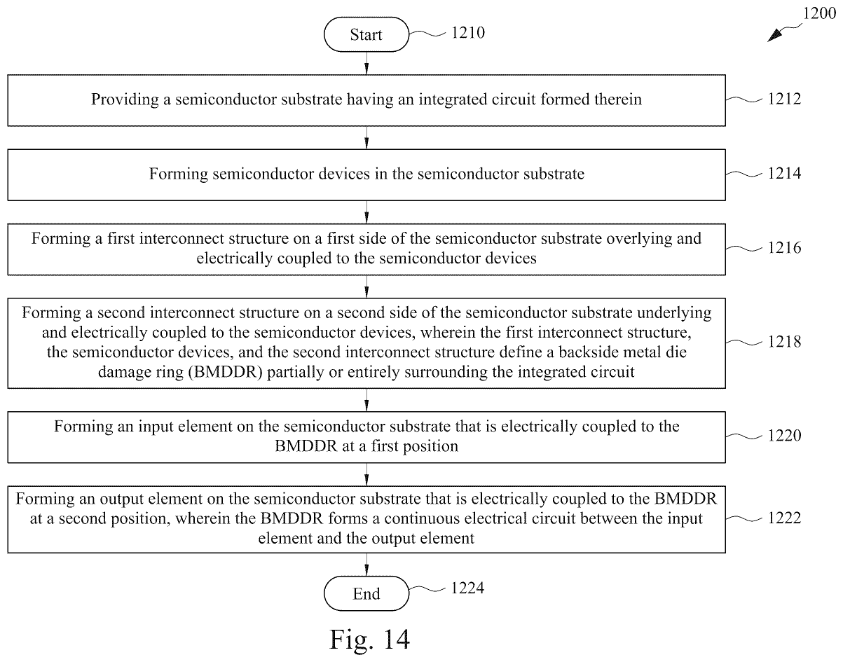

Referring to FIG. 14, an exemplary method 1200 is presented for fabrication of a semiconductor structure. The method 1200 may start at 1210. At 1212, the method 1200 may include providing a semiconductor substrate having an integrated circuit formed therein. Various methods are known in the art that may be used to produce the semiconductor substrate and the integrated circuit therein, and therefore such processes are not discussed in detail herein.

At 1214, the method 1200 may include forming semiconductor devices in the semiconductor substrate. Various methods are known in the art that may be used to produce the semiconductor devices and therefore such processes are not discussed in detail herein.

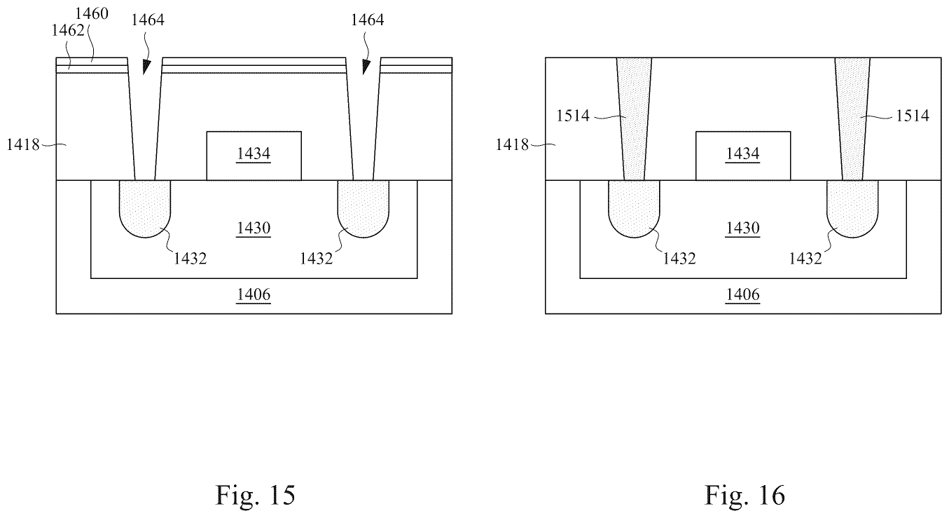

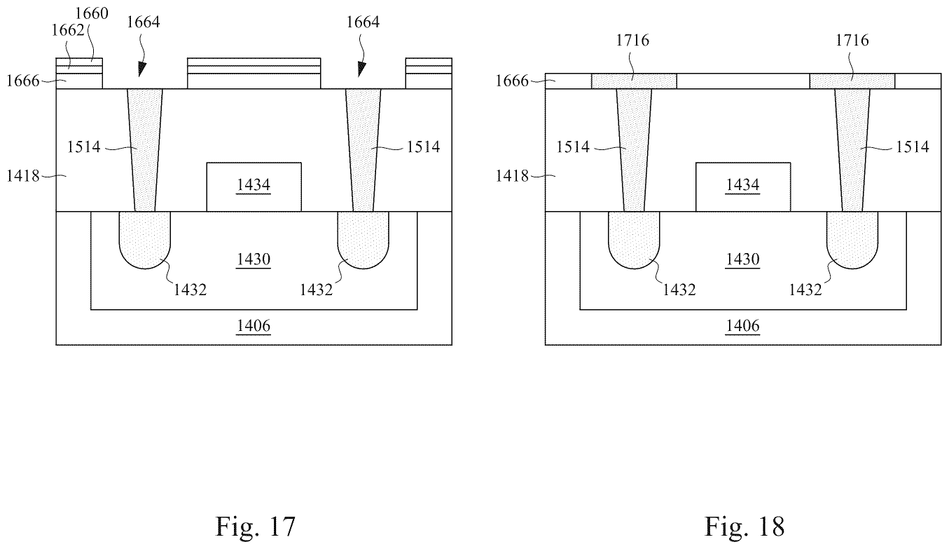

At 1216, the method 1200 may include forming a first interconnect structure on the first side of the semiconductor substrate overlying and electrically coupled to the semiconductor devices. Various methods may be used for forming the first interconnect structure. For example, FIG. 15 illustrates a nonlimiting example in which trenches or openings 1464 are formed in first and second masking layers 1460, 1462, and an inter-layer dielectric layer 1418 over a semiconductor substrate 1406. In this example, the semiconductor substrate 1406 includes a semiconductor device having a doped well region 1430, source/drain structures 1432 therein, and a gate electrode 1434 thereon. Portions of source/drain structures 1432 may be exposed at bases of the openings 1464. Optionally, a liner (not shown) may be formed covering sidewalls of the openings 1464 in the inter-layer dielectric layer 1418. The openings 1464 may be filled with a conductive layer (i.e., fill material). In some embodiments, the conductive layer may include a metal or alloy of high electric conductivity. As nonlimiting examples, the conductive layer may include copper (Cu), aluminum (Al), tungsten (W), silver (Ag), or alloys thereof. A CMP process may be performed to remove a portion of the conductive layer and/or the liner and form a flush surface over the dielectric structure. FIG. 16 illustrates a nonlimiting example in which the openings 1464 have been filled with a conductive material to define interconnect vias 1514, and the first and second masking layers 1460, 1462 have been removed. This process may be repeated for each layer of the first interconnect structure. For example, FIG. 17 illustrates a nonlimiting example in which second openings 1664 are formed in third and fourth masking layers 1660, 1662, and a first IMD layer 1666 over the inter-layer dielectric layer 1418, and FIG. 18 illustrates a nonlimiting example in which the second openings 1664 have been filled with a conductive material to define interconnect metal layers 1716, and the third and fourth masking layers 1660, 1662 have been removed.

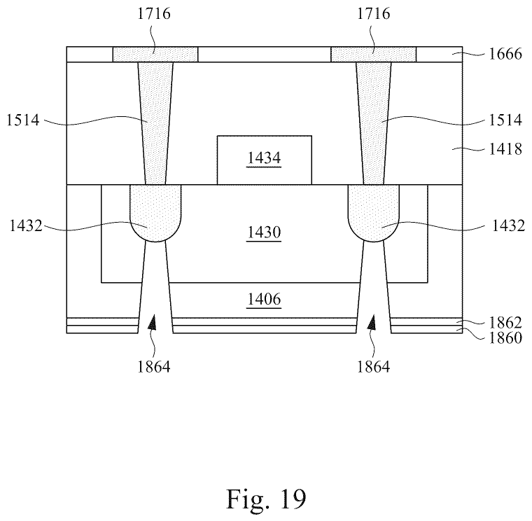

At 1218, the method 1200 may include forming a second interconnect structure on a second side of the semiconductor substrate underlying and electrically coupled to the semiconductor devices, wherein the first interconnect structure, the semiconductor devices, and the second interconnect structure define a backside metal die damage ring (BMDDR) partially or entirely surrounding the integrated circuit. For example, FIG. 19 illustrates a nonlimiting example in which trenches or openings 1864 are formed through fifth and sixth masking layers 1860, 1862 and the backside of the semiconductor substrate 1406 such that the openings 1864 are open to the backside of the semiconductor substrate 1406. The fifth and sixth masking layers 1860, 1860 may be formed on the backside of the semiconductor substrate 1406, for example, by a film deposition process. Various processes may be used to form the openings 1864, such as one or more photolithography and etching processes. In some embodiments, the openings 1864 may be formed to a depth sufficient such that bases of the openings 1864 are defined by a portion of the source/drain structures 1432 of the semiconductor devices. Optionally, an isolation layer may be formed in the openings 1864, for example, by a physical vapor deposition (PVD) process.

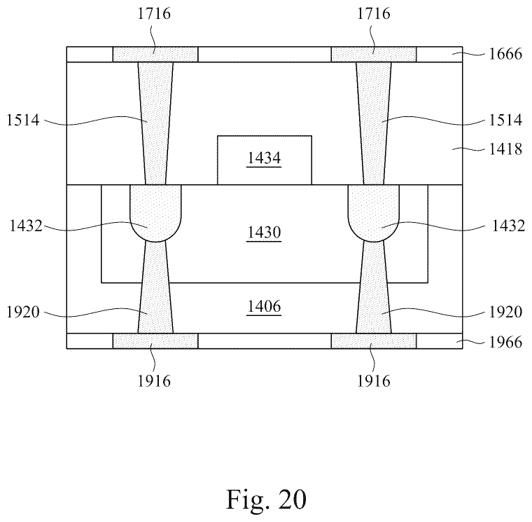

Conductive elements 1920 (e.g., TSVs) may be formed in the openings 1864 by depositing conductive materials into the openings 1864 that are exposed at the backside of the semiconductor substrate 1406, extend through the semiconductor substrate 1406, and electrically couple with the source/drain structures 1432 of the semiconductor device. The conductive elements 1920 may be formed of or include various conductive materials. Nonlimiting examples include various metallic materials such as titanium-titanium nitride-tungsten alloys, tungsten, cobalt, ruthenium, molybdenum, etc. The fifth and sixth masking layers 1860, 1862 and any other excess materials (e.g., portions of the first conductive elements) may be removed, for example, by a CMP process. FIG. 20 illustrates a nonlimiting example in which interconnect metal layers 1916 have been formed a second IMD layer 1966 by a process substantially similar as described in reference to FIGS. 17 and 18.

At 1220, the method 1200 may include forming an input element on the semiconductor substrate that is electrically coupled to the BMDDR at a first position, and at 1222, the method 1200 may include forming an output element on the semiconductor substrate that is electrically coupled to the BMDDR at a second position, wherein the BMDDR forms a continuous electrical circuit between the input element and the output element. Various methods are known in the art that may be used to produce the input and output elements, and therefore such processes are not discussed in detail herein.

The method 1200 may end at 1224.

The present disclosure therefore provides semiconductor structures and methods for manufacturing and testing semiconductor structures that provide for detection of damage, for example, that occurred during a die cutting process. In some embodiments, the semiconductor structures include a backside metal die damage ring that defines an electrical circuit about an integrated circuit.

In accordance with an embodiment, a semiconductor structure is provided that includes an integrated circuit formed in a semiconductor substrate, a seal ring on at least a first side of the semiconductor substrate and surrounding a perimeter of the integrated circuit, an input element, an output element, and a backside metal die damage ring (BMDDR) disposed on the first side of the semiconductor substrate, extending through the semiconductor substrate, and disposed on a second side of the semiconductor substrate, the BMDDR disposed between the integrated circuit and the seal ring, the BMDDR at least partially surrounding the perimeter of the integrated circuit, the BMDDR coupled to and forming an electrical circuit between the input element and the output element.

In accordance with another embodiment, a method is provided that includes providing a semiconductor substrate having an integrated circuit formed therein and a backside metal die damage ring (BMDDR) disposed on a first side of the semiconductor substrate, extending through the semiconductor substrate, and disposed on a second side of the semiconductor substrate, the BMDDR at least partially surrounding the perimeter of the integrated circuit, and detecting damage to the BMDDR by applying an electrical load to the BMDDR between an input element and an output element each coupled thereto to detect a disconnect in an electrical circuit defined by the BMDDR.

In accordance with yet another embodiment, a method is provided that includes providing a semiconductor substrate having an integrated circuit formed therein, forming semiconductor devices in the semiconductor substrate, forming a first interconnect structure on a first side of the semiconductor substrate overlying and electrically coupled to the semiconductor devices, forming a second interconnect structure on a second side of the semiconductor substrate underlying and electrically coupled to the semiconductor devices, wherein the first interconnect structure, the semiconductor devices, and the second interconnect structure define a backside metal die damage ring (BMDDR) partially or entirely surrounding the integrated circuit, forming an input element on the semiconductor substrate that is electrically coupled to the BMDDR at a first position, and forming an output element on the semiconductor substrate that is electrically coupled to the BMDDR at a second position, wherein the BMDDR forms a continuous electrical circuit between the input element and the output element.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor structure, comprising:
an integrated circuit formed in a semiconductor substrate;
a seal ring on at least a first side of the semiconductor substrate and surrounding a perimeter of the integrated circuit;
an input element;
an output element; and
a backside metal die damage ring (BMDDR) disposed on the first side of the semiconductor substrate, extending through the semiconductor substrate, and disposed on a second side of the semiconductor substrate, the BMDDR disposed between the integrated circuit and the seal ring, the BMDDR at least partially surrounding the perimeter of the integrated circuit, the BMDDR coupled to and forming an electrical circuit between the input element and the output element.

2. The semiconductor structure of claim 1, wherein the BMDDR includes an interconnect structure coupled to one or more semiconductor devices formed in the semiconductor substrate.

3. The semiconductor structure of claim 1, wherein the BMDDR includes a first interconnect structure disposed on the first side of the semiconductor substrate, and a second interconnect structure disposed on a second side of the semiconductor substrate, wherein the first interconnect structure and the second interconnect structure are electrically coupled by first semiconductor devices formed in the semiconductor substrate.

4. The semiconductor structure of claim 3, wherein the first interconnect structure and the second interconnect structure are each coupled to source/drain structures of the first semiconductor devices therebetween.

5. The semiconductor structure of claim 4, wherein the second interconnect structure is coupled to the source/drain structures by through substrate vias formed in the second side of the semiconductor substrate.

6. The semiconductor structure of claim 1, wherein the BMDDR includes a plurality of first units of a first interconnect structure disposed on the first side of the semiconductor substrate, and a plurality of second units of a second interconnect structure disposed on a second side of the semiconductor substrate, wherein the plurality of the first units and the plurality of the second units are electrically coupled to each other in series such that the first units and the second units alternate linearly along the BMDDR and are electrically coupled by semiconductor devices formed in the semiconductor substrate.

7. The semiconductor structure of claim 6, wherein the plurality of the first units and the plurality of the second units are coupled along the BMDDR in a serpentine pattern.

8. The semiconductor structure of claim 6, wherein the input element and the output element are pins coupled to the second interconnect structure on the second side of the semiconductor substrate.

9. The semiconductor structure of claim 1, wherein the input element and the output element are pads coupled to the integrated circuit.

10. A method, comprising:
providing a semiconductor substrate having an integrated circuit formed therein and a backside metal die damage ring (BMDDR) disposed on a first side of the semiconductor substrate, extending through the semiconductor substrate, and disposed on a second side of the semiconductor substrate, the BMDDR at least partially surrounding the perimeter of the integrated circuit; and
detecting damage to the BMDDR by applying an electrical load to the BMDDR between an input element and an output element each coupled thereto to detect a disconnect in an electrical circuit defined by the BMDDR.

11. The method of claim 10, wherein detecting damage to the BMDDR includes measuring a change in resistance or conductivity of the electrical circuit.

12. The method of claim 10, further comprising inspecting the integrated circuit for damage thereto in response to detecting damage to the BMDDR.

13. The method of claim 10, wherein the BMDDR includes a plurality of first units of a first interconnect structure disposed on the first side of the semiconductor substrate, and a plurality of second units of a second interconnect structure disposed on a second side of the semiconductor substrate, wherein the plurality of the first units and the plurality of the second units are electrically coupled to each other in series such that the first units and the second units alternate linearly along the BMDDR and are electrically coupled by semiconductor devices formed in the semiconductor substrate.

14. The method of claim 13, wherein the plurality of the first units and the plurality of the second units are coupled along the BMDDR in a serpentine pattern.

15. A method, comprising:
providing a semiconductor substrate having an integrated circuit formed therein;
forming semiconductor devices in the semiconductor substrate;
forming a first interconnect structure on a first side of the semiconductor substrate overlying and electrically coupled to the semiconductor devices;
forming a second interconnect structure on a second side of the semiconductor substrate underlying and electrically coupled to the semiconductor devices, wherein the first interconnect structure, the semiconductor devices, and the second interconnect structure define a backside metal die damage ring (BMDDR) partially or entirely surrounding the integrated circuit;
forming an input element on the semiconductor substrate that is electrically coupled to the BMDDR at a first position; and
forming an output element on the semiconductor substrate that is electrically coupled to the BMDDR at a second position, wherein the BMDDR forms a continuous electrical circuit between the input element and the output element.

16. The method of claim 15, wherein the first interconnect structure and the second interconnect structure are each coupled to source/drain structures of the semiconductor devices.

17. The method of claim 15, further comprising forming through substrate vias in the second side of the semiconductor substrate that electrically couple the semiconductor devices and the second interconnect structure.

18. The method of claim 15, wherein the method includes forming the first interconnect structure to include a plurality of first units and the second interconnect structure to include a plurality of second units, wherein the plurality of the first units and the plurality of the second units are electrically coupled to each other in series such that the first units and the second units alternate linearly along the BMDDR and are electrically coupled by the semiconductor devices formed in the semiconductor substrate.

19. The method of claim 18, wherein the plurality of the first units and the plurality of the second units are coupled along the BMDDR in a serpentine pattern.

20. The method of claim 15, further comprising forming a seal ring on the semiconductor substrate that entirely surrounds a perimeter of the BMDDR and the perimeter of the integrated circuit.
